(19) United States
(12) Patent Application Publication
(10) Pub. No.: US 2012/0182063 A1
(43) Pub. Date: Jul. 19, 2012

(54) Power Device Using Photoelectron Injection to Modulate Conductivity and the Method Thereof

(75) Inventors: Pengfei Wang, Shanghai (CN); Qingqing Sun, Shanghai (CN); Shijin Ding, Shanghai (CN); Wei Zhang, Shanghai (CN)

(73) Assignee: Fundan University, Shanghai (CN)

(21) Appl. No.: 13/498,778

(22) PCT Filed: Apr. 21, 2011
(86) PCT No.: PCT/CN2011/000698

§ 371 Date: Mar. 28, 2012

(30) Foreign Application Priority Data
Apr. 22, 2010 (CN) 201010153505.3

(51) Int. Cl. H01L 31/167

(52) U.S. Cl. 327/514; 257/83; 257/E31.037

(57) ABSTRACT

The present invention belongs to the technical field of semiconductor devices, and discloses a power device using photoelectron injection to modulate conductivity and the method thereof. The power device comprises at least one photoelectron injection light source and a power MOS transistor. The present invention uses photoelectron injection method to inject carriers to the drift region under the gate of the power MOS transistor, thus modulating the conductivity and further decreasing the specific on-resistance of the power MOS transistor. Moreover, as the doping concentration of the drift region can be decreased and the blocking voltage can be increased, the performance of the power MOS transistor can be greatly improved and the application of power MOS transistor can be expanded to high-voltage fields.

### BACKGROUND OF THE INVENTION

1. Technical Field

The present invention belongs to the technical field of semiconductor devices, and relates to a semiconductor power device, especially to a power device using photoelectron injection to modulate conductivity. The present invention also relates to a method for modulating the conductivity of a power device by using photoelectron injection.

2. Description of the Related Art

In last two decades, with the rapid development of power devices and their packaging technology, the power MOS transistor especially, has replaced the traditional bipolar transistor in many application fields because of its excellent performance (high input impedance and short turn-off time, etc.). The power MOS transistor is mainly used as a switch device in power circuits. The on-state power consumption of the power MOS transistor is high. To decrease the on-state power consumption, the on-resistance Rds (on) must be reduced. Traditional power MOS transistors usually use a vertical double-diffusion structure. FIG. 1a shows a traditional n-type power MOS transistor structure, comprising a highly-concentrated n-type substrate 101 at the bottom, an n-type drift region 102 on the extension of the substrate 101, and a polycrystalline silicon 108 and a gate oxide layer 107 used as the mask to realize double diffusion so as to form P+ regions 103 and 104, and n+ regions 105 and 106. The breakdown voltage of a power MOS transistor is mainly represented by the PN junction formed on c and the drift region 102. Therefore, the drift region 102 shall have large thickness and a low doping concentration so as to achieve a high breakdown voltage. However, with the constant increase of breakdown voltage and the decrease of the doping concentration of the drift region, the thickness of the drift region 102 increases, leading to the rising of the resistance of the drift region 102 used as current pathway, and further leading to the increase of on-resistance Rds (on) and the on-state power consumption. The conflict between the breakdown voltage and on-resistance Rds (on) restricts the development of power MOS transistors in high-voltage application fields.

To address the above problems, a super junction structure is currently proposed. FIG. 1b shows an n-type power MOS transistor structure using super junction. Like traditional power MOS transistor, it comprises a highly-concentrated n-type substrate 111 at the bottom, an n-type drift region 112 on the extension of the substrate 111, a polycrystalline silicon 120 and a gate oxide layer 119 used as a mask to realize double diffusion so as to form P+ regions 115 and 116, and n+ regions 117 and 118. The difference is that, two P− regions 113 and 114 are inserted in the drift region 112 of the n-type power MOS transistor structure using a super junction, thus forming a PN junction structure. When applying reverse bias voltage to the drift region 112, a transverse voltage depleting the PN junction will be generated. When the reverse bias voltage reaches a certain value, the drift region 112 will be completely depleted. The doping concentration of the drift area 112 of the n-type power MOS transistor using super junction can be increased by 1-2 two orders of magnitude, thus reducing the on-resistance Rds (on) under same breakdown voltage significantly. However, the technical process of the super junction is complex, and the parameter requirements for the devices and the production cost are very high.

### BRIEF SUMMARY OF THE INVENTION

The present invention aims at providing a new type of power MOS transistor capable of increasing the blocking voltage when decreasing the on-resistance Rds (on), thus to enable the development of power MOS transistor in the high-voltage application fields.

A power device using photoelectron injection to modulate conductivity put forward by the present invention comprises at least one photoelectron injection light source and a power MOS transistor. The photoelectron light source is a light emitting diode (LED), and the power MOS transistor is a planar power MOS transistor, or a trench-gate power MOS transistor or a power MOS transistor of other structures.

Furthermore, the photoelectron injection light source is configured above the substrate surface of the power MOS transistor. The anode and cathode of the photoelectron injection light source are connected with the gate and source of the power MOS transistor respectively; or the cathode and anode of the photoelectron injection light source are connected with the gate and source of the power MOS transistor respectively.

Moreover, the present invention also provides a method for modulating the conductivity of the power devices above by using photoelectron injection, and the detailed steps are as follows:

Provide a photoelectron injection light source;

Use the photoelectron injection light source to illuminate the substrate surface of the power MOS transistor.

The drift region under the power MOS transistor gate can be injected with photoelectrons;

The drift region receiving photoelectrons is a photoelectric conductor;

The conductivity of the photoelectric conductor can be modulated by controlling the photoelectron injection;

The decrease of the photoelectric conductor resistance leads to the decrease of the on-resistance of the power MOS transistor.

Inject carriers to the drift region under the power device gate by means of photoelectron injection to modulate the conductivity, thus decreasing the specific on-resistance. Moreover, as the doping concentration of the drift region can be decreased and the blocking resistance can be increased, the performance of power devices can be improved significantly, thus enabling the application of power MOS transistors in high-voltage fields such as automobile electronic products, power switches, AC-DC, AC-AC and DC-AC rectifiers.

### BRIEF DESCRIPTION OF THE SEVERAL VIEWS OF THE DRAWINGS

FIG. 1a is the sectional view of a traditional power MOS transistor structure.

FIG. 1b is the sectional view of a power MOS transistor structure using a super junction.

FIG. 2 is an operation diagram of an embodiment of a method for modulating the conductivity of a trench-gate power MOS transistor by using photoelectron injection provided by the present invention.

FIG. 3 is the equivalent circuit diagram when modulating the conductivity of a trench-gate power MOS transistor by using photoelectron injection as shown in FIG. 2.

FIG. 4 is the structural diagram of the power device using photoelectron injection to modulate conductivity after assembly and packaging.

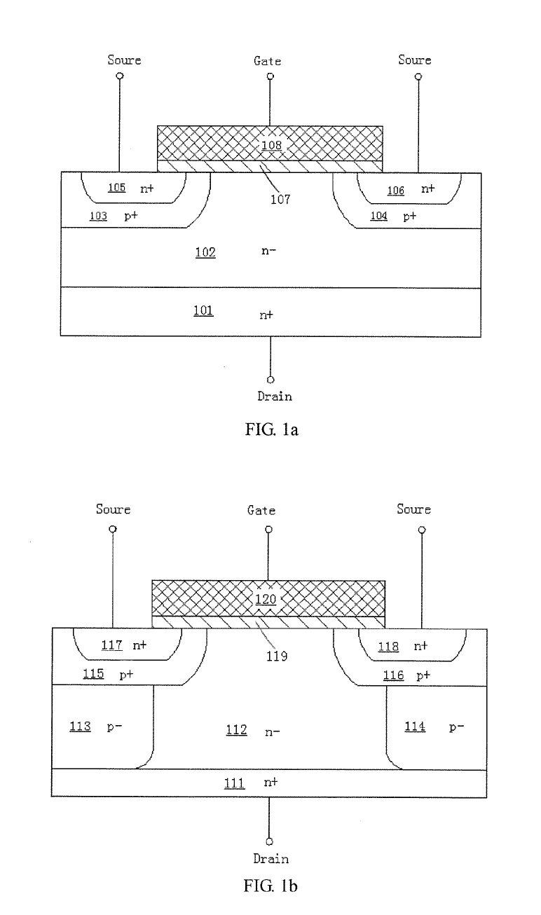

### DETAILED DESCRIPTION OF THE INVENTION

An exemplary embodiment of the present invention is further detailed by referring to the drawings below. In the drawings, for the convenience of description, the thickness of the layers and regions is magnified and the dimensions shown do not represents the actual ones. Although these drawings do not represent the actual device dimensions accurately, they show the relative positions of the regions and structures completely, especially the vertical and horizontal relations.

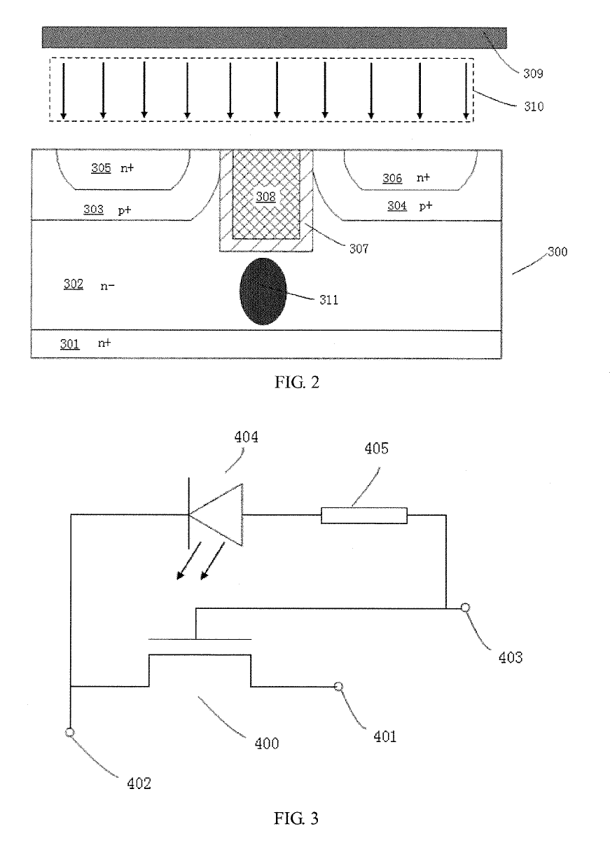

FIG. 2 is the operation diagram of modulating the conductivity of an n-type trench-gate power MOS transistor by using photoelectron injection. As shown in FIG. 2, put a light emitting diode (LED) 309 above the substrate surface of a power MOS transistor 300, thus the LED 309 can inject photoelectrons to the MOS transistor 300, wherein the diagram in the dashed box 310 is the light illumination diagram. The power MOS transistor 300 comprises a drain area 301, a drift layer 302, p-type diffusion regions 303 and 304, source regions 305 and 306, a gate 308 and a gate oxide layer 307. The photoelectrons are injected in the drift layer 302 and the drift region receiving photoelectrons under the gate region is a conductivity modulation region 311. Under the condition that the doping concentration of the drift region decreases, the resistance of the photo-conductor can be decreased by controlling the photoelectron injection, thus the on-resistance of the power MOS transistor 300 can be decreased. The decrease of the doping concentration of the drift region causes the blocking voltage increase of the power MOS transistor, so enabling the development of the power MOS transistor towards high-voltage fields.

FIG. 3 is the equivalent circuit diagram when modulating the conductivity of an n-type trench-gate power MOS transistor by using photoelectron injection as shown in FIG. 2. As shown in FIG. 3, connect the gate of a power MOS transistor 400 with the input end and the anode of a LED 404 through a resistance 405, the source with the ground 402 and the cathode of the LED 404, and the drain with the output end 401. When the gate of the power MOS transistor inputs positive voltage, the LED 404 will generate radiation to illuminate the MOS transistor 400, thus modulating the conductivity of the power MOS transistor 400 through photoelectron injection and reducing the on-resistance of the power MOS transistor.

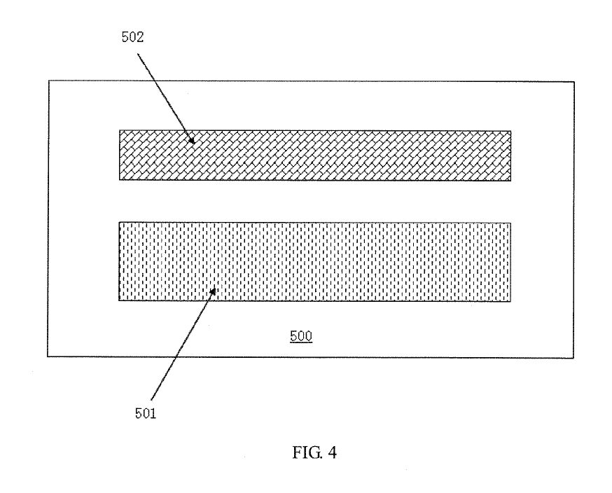

FIG. 4 is the structural diagram of the power device using photoelectron injection to modulate conductivity after assembly and packaging. As shown in FIG. 4, an LED 502 and a power MOS transistor 501 integrated in a chip 500, wherein the LED 502 is configured above the substrate surface of the MOS transistor 501.

As described above, there are many significantly different embodiments without deviating from the spirit and scope of the present invention. It shall be understood that the present invention is not limited to the specific embodiments described in the Specification except those limited by the Claims herein.

1. A power device using photoelectron injection to modulate conductivity comprises at least one photoelectron injection light source and a power MOS transistor.

2. The power device using photoelectron injection to modulate conductivity of claim 1, wherein the photoelectron light source is a light emitting diode.

3. The power device using photoelectron injection to modulate conductivity of claim 1, wherein the power MOS transistor is a planar power MOS transistor, or a trench-gate power MOS transistor.

4. The power device using photoelectron injection to modulate conductivity of claim 1, wherein the anode of the photoelectron injection light source are connected with the gate of the power MOS transistor; the cathode of the photoelectron injection light source are connected with the source of the power MOS transistor.

5. The power device using photoelectron injection to modulate conductivity of claim 1, wherein the cathode of the photoelectron injection light source are connected with the gate and source of the power MOS transistor; the anode of the photoelectron injection light source are connected with the source of the power MOS transistor.

6. The power device using photoelectron injection to modulate conductivity of claim 1, wherein the photoelectron injection light source is configured above the substrate surface of the power MOS transistor.

7. A method for modulating the conductivity of the power devices by using photoelectron injection and the detailed steps are as follows:
provide a photoelectron injection light source;
use the photoelectron injection light source to illuminate the substrate surface of the power MOS transistor;
the drift region under the power MOS transistor gate can be injected with photoelectrons;
the conductivity of the photoelectric conductor can be modulated by controlling the photoelectron injection;
the decrease of the photoelectric conductor resistance leads to the decrease of the on-resistance of the power MOS transistor.

8. The method for modulating the conductivity of the power devices by using photoelectron injection of claim 7, wherein the photoelectron light source is a light emitting diode.

9. The method for modulating the conductivity of the power devices by using photoelectron injection of claim 7, wherein the power MOS transistor is a planar power MOS transistor, or a trench-gate power MOS transistor.
